(19) United States
(12) Patent Application Publication
(10) Pub. No.: US 2026/0033048 A1
(43) Pub. Date: Jan. 29, 2026

(54) REFLECTIVE STRUCTURES FOR LIGHT-EMITTING DIODE CHIPS AND RELATED METHODS

(71) Applicant: CreeLED, Inc., Durham, NC (US)

(72) Inventors: Michael Check, Holly Springs, NC (US); Steven Wuester, Wake Forest, NC (US); Nikolas Hall, Durham, NC (US)

(21) Appl. No.: 18/787,476

(22) Filed: Jul. 29, 2024

(51) Int. Cl. H01L 33/46; H01L 33/00; H01L 33/30

(52) U.S. Cl. CPC H10H 20/841; H10H 20/0133; H10H 20/034; H10H 20/8242

(57) ABSTRACT

Solid-state lighting devices including light-emitting diodes (LEDs) and more particularly reflective structures for LED chips and related methods are disclosed. Reflective structures include arrangements of a first metal and a second metal within a metal reflective layer. The second metal may have a nonuniform distribution throughout a thickness of the metal reflective layer relative to the first metal. The first metal may promote increased reflectivity relative to the second metal, and the second metal may promote increased mechanical stability, increased adhesion, and reduced electromigration. An exemplary metal reflective layer includes increased concentrations of the second metal near interfaces between the metal reflective layer and other layers of the LED chip. The second metal may also form concentration gradients in directions away from the interfaces. Related methods include sequentially forming discrete layers of the first and second metals, followed by annealing to form the metal reflective layer.

### FIELD OF THE DISCLOSURE

The present disclosure relates to solid-state lighting devices including light-emitting diodes (LEDs) and more particularly to reflective structures for LED chips and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An active region may be fabricated, for example, from silicon carbide, gallium nitride, gallium phosphide, aluminum nitride, and/or gallium arsenide-based materials and/or from organic semiconductor materials. Photons generated by the active region are initiated in all directions.

Typically, it is desirable to operate LEDs at the highest light emission efficiency, which can be measured by the emission intensity in relation to the output power (e.g., in lumens per watt). A practical goal to enhance emission efficiency is to maximize extraction of light emitted by the active region in the direction of the desired transmission of light. Light extraction and external quantum efficiency of an LED can be limited by how well current is able to spread within an LED and by internal absorption of photons that fail to exit LED chip structures.

As advancements in modern LED technology progress, the art continues to seek improved LEDs and solid-state lighting devices having desirable illumination characteristics capable of overcoming challenges associated with conventional lighting devices.

### SUMMARY

The present disclosure relates to solid-state lighting devices including light-emitting diodes (LEDs) and more particularly to reflective structures for LED chips and related methods. Reflective structures include arrangements of a first metal and a second metal within a metal reflective layer. The second metal may have a nonuniform distribution throughout a thickness of the metal reflective layer relative to the first metal. The first metal may promote increased reflectivity relative to the second metal, and the second metal may promote increased mechanical stability, increased adhesion, and reduced electromigration relative to the first metal. An exemplary metal reflective layer may include increased concentrations of the second metal near interfaces between the metal reflective layer and other layers of the LED chip. The second metal may also form concentration gradients in directions away from the interfaces. Related methods include sequentially forming discrete layers of the first and second metals, followed by annealing to form the metal reflective layer.

In one aspect, an LED chip comprises: an active LED structure comprising an n-type layer, a p-type layer, and an active layer between the n-type layer and the p-type layer; and a metal reflective layer on the active LED structure, the metal reflective layer comprising: a first region and a second region, the second region being closer to the active LED structure than the first region; and a first metal and a second metal that is different than the first metal, a concentration of the first metal being higher than a concentration of the second metal in the first region, and the concentration of the second metal being higher than the concentration of the first metal in the second region. In certain embodiments, the concentration of the second metal forms a first gradient that decreases within the second region in a direction toward the first region. The LED chip may further comprise a dielectric reflective layer between the metal reflective layer and the active LED structure, the second region being closer to the dielectric reflective layer than the first region. In certain embodiments, the second region forms a first interface between the metal reflective layer and the dielectric reflective layer. The LED chip may further comprise an adhesion layer between the metal reflective layer and the dielectric reflective layer, wherein the second region forms a first interface between the metal reflective layer and the adhesion layer. In certain embodiments, the adhesion layer is discontinuous such that the second region further forms the first interface between the metal reflective layer and both of the dielectric reflective layer and the adhesion layer. In certain embodiments, the metal reflective layer further comprises a third region, wherein: the third region is farther away from the active LED structure than both the first region and the second region; the concentration of the second metal is higher than the concentration of the first metal in the third region; and the concentration of the second metal forms a second gradient that decreases within the third region in a direction toward the first region. The LED chip may further comprise a barrier layer on the metal reflective layer, wherein the third region forms a second interface between the metal reflective layer and the barrier layer. In certain embodiments, the first metal comprises silver and the second metal comprises indium. In certain embodiments, the first metal comprises silver and the second metal comprises at least one of one of tin, zinc, or tin-silver-copper.

In another aspect, a method for forming an LED chip comprises: forming an active LED structure comprising an n-type layer, a p-type layer, and an active layer between the n-type layer and the p-type layer; and forming a metal reflective layer having a first metal and a second metal on the active LED structure, the forming the metal reflective layer comprising: depositing a first layer comprising the second metal on the active LED structure; depositing a second layer comprising the first metal on the first layer; and annealing the first layer and the second layer to form the metal reflective layer with a nonuniform distribution of the second metal relative to the first metal. In certain embodiments, the nonuniform distribution comprises a first region and a second region, wherein the second region is closer to the active LED structure than the first region, wherein a concentration of the first metal is higher than a concentration of the second metal in the first region, and the concentration of the second metal is higher than the concentration of the first metal in the second region. In certain embodiments, the concentration of the second metal forms a first gradient that decreases within the second region in a direction toward the first region. The method may further comprise forming a dielectric reflective layer between the metal reflective layer and the active LED structure, the second region being closer to the dielectric reflective layer than the first region. In certain embodiments, the second region forms a first interface between the metal reflective layer and the dielectric reflective layer. In certain embodiments, the nonuniform distribution comprises a third region, wherein: the third region is farther away from the active LED structure than both the first region and the second region; the concentration of the second metal is higher than the concentration of the first metal in the third region; and the concentration of the second metal forms a second gradient that decreases within the third region in a direction toward the first region. The method may further comprise forming a barrier layer on the metal reflective layer after annealing the first layer and the second layer, wherein the third region forms a second interface between the metal reflective layer and the barrier layer. The method may further comprise forming a barrier layer on the metal reflective layer before annealing the first layer and the second layer, wherein the third region forms a second interface between the metal reflective layer and the barrier layer. In certain embodiments, the first metal comprises silver and the second metal comprises indium. In certain embodiments, the first metal comprises silver and the second metal comprises at least one of one of tin, zinc, or tin-silver-copper

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTiON OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of an exemplary light-emitting diode (LED) chip with a metal reflective layer with first and second metals according to principles of the present disclosure.

FIG. 2 is a cross-sectional view of a portion of the LED chip of FIG. 1 at a fabrication step after formation of the metal reflective layer and a barrier layer.

FIG. 3A is a cross-sectional view of a portion of the LED chip of FIG. 2 at a fabrication step before an annealing process is employed to form the metal reflective layer with nonuniform distributions of the second metal relative to the first metal.

FIG. 3B is a cross-sectional view of a portion of the LED chip of FIG. 3A at a subsequent fabrication step after annealing to form the metal reflective layer.

FIG. 4A is a cross-sectional view of the LED chip for an alternative annealing sequence relative to FIGS. 3A to 3B where individual layers that will form the metal reflective layer are formed.

FIG. 4B is a cross-sectional view of a portion of the LED chip of FIG. 4A at a subsequent fabrication step after annealing to form the metal reflective layer is provided before the barrier layer is formed.

FIG. 4C is a cross-sectional view of a portion of the LED chip of FIG. 4B at a subsequent fabrication step after the barrier layer is formed on the previously annealed metal reflective layer.

FIG. 5 is a cross-sectional of the LED chip similar to FIG. 3B or FIG. 4C for embodiments that include the adhesion layer.

FIG. 6 is a cross-sectional view of the LED chip similar to FIG. 5 for embodiments where the adhesion layer is a discontinuous layer.

FIG. 7A is a cross-sectional view of a portion of the LED chip of FIG. 1 after formation of the metal reflective layer and the barrier layer and before photolithography lift-off.

FIG. 7B is a cross-sectional view of a portion of the LED chip of FIG. 7A after lift-off of a photoresist and illustrating no edge damage defects according to aspects of the present disclosure.

FIG. 7C is a cross-sectional view taken from a portion of the LED chip of FIG. 7B as indicated by the superimposed dashed-line box labeled 7C.

### DETAILED DESCRIPTiON

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to reflective structures for LED chips and related methods. Reflective structures include arrangements of a first metal and a second metal within a metal reflective layer. The second metal may have a nonuniform distribution throughout a thickness of the metal reflective layer relative to the first metal. The first metal may promote increased reflectivity relative to the second metal, and the second metal may promote increased mechanical stability, increased adhesion, and reduced electromigration relative to the first metal. An exemplary metal reflective layer may include increased concentrations of the second metal near interfaces between the metal reflective layer and other layers of the LED chip. The second metal may also form concentration gradients in directions away from the interfaces. Related methods include sequentially forming discrete layers of the first and second metals, followed by annealing to form the metal reflective layer.

An LED chip typically comprises an active LED structure or region that may have many different semiconductor layers arranged in different ways. The fabrication and operation of LEDs and their active structures are generally known in the art and are only briefly discussed herein. The layers of the active LED structure may be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, un-doped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), aluminum nitride (AlN), and GaN.

Different embodiments of the active LED structure can emit different wavelengths of light depending on the composition of the active layer and n-type and p-type layers. In certain embodiments, the active LED structure may emit blue light with a peak wavelength range of approximately 430 nanometers (nm) to 480 nm. In other embodiments, the active LED structure may emit green light with a peak wavelength range of 500 nm to 570 nm. In other embodiments, the active LED structure may emit red light with a peak wavelength range of 600 nm to 650 nm. In certain embodiments, the active LED structure may emit light with a peak wavelength in any area of the visible spectrum, for example peak wavelengths primarily in a range from 400 nm to 700 nm.

In certain embodiments, the active LED structure may be configured to emit light that is outside the visible spectrum, including one or more portions of the ultraviolet (UV) spectrum, the infrared (IR) or near-IR spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. In certain applications, UV LEDs may also be provided with one or more lumiphoric materials to provide LED packages with aggregate emissions having a broad spectrum and improved color quality for visible light applications. Near-IR and/or IR wavelengths for LED structures of the present disclosure may have wavelengths above 700 nm, such as in a range from 750 nm to 1100 nm, or more.

The present disclosure can be useful for LED chips having a variety of geometries, such as vertical and/or flip-chip geometries. A vertical geometry LED chip typically includes anode and cathode connections on opposing sides or faces of the LED chip. In certain embodiments, a vertical geometry LED chip may also include a growth substrate that is arranged between the anode and cathode connections. In certain embodiments, LED chip structures may include a carrier submount and where the growth substrate is removed. In still further embodiments, any of the principles described herein are applicable to flip-chip structures where anode and cathode connections are made from a same side of the LED chip for flip-chip mounting to another surface. In certain flip-chip embodiments, the growth substrate of the LED chip may form the intended light-exiting surface for the LED chip.

Light emitted by the active layer or region of an LED chip is typically initiated in multiple directions. For directional applications, internal mirrors or external reflective surfaces may be employed to redirect as much light as possible toward a desired emission direction. Internal mirrors may include single or multiple layers. Some multi-layer mirrors include a metal reflective layer and a dielectric reflective layer, wherein the dielectric reflective layer is arranged between the metal reflective layer and a plurality of semiconductor layers. A passivation layer is arranged between the metal reflective layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

In LED chip arrangements, reflective structures that embody mirrors may be formed along one side of an active LED structure to redirect light toward an opposing side in an intended emission direction. Such reflective structures may include a metal reflective layer. In certain embodiments, the metal reflective layer may embody a sputtered metal layer, that is, the metal reflective layer is formed by sputter deposition. In other embodiments, the metal reflective layer may be formed by other deposition techniques, such as evaporation, electron beam deposition, ion assisted electron beam deposition, and thermal evaporation, among other physical vapor deposition processes. As known to those skilled in the art, a sputtered metal layer in an LED chip structure has a readily identifiable film structure or morphology by way of scanning electron microscopy (SEM) and/or focused ion beam (FIB) microscopy. For example, a sputtered metal layer may have a larger grain size than a metal layer of the same material formed by other common deposition techniques, such as electron beam deposition.

Despite the advantages of improved reflectivity, some metal reflective layers may provide challenges during fabrication of LED chips. For example, certain metals commonly employed as metal reflective layers, such as Ag among others, are prone to electromigration. With an applied voltage for electrically activating an LED structure, the metal may tend to migrate due to a so-called electron wind effect. Such migration may further be exacerbated by the presence of moisture. Migration may cause metal dendrites to spread from the metal reflective layer, thereby increasing the chance of cracking and/or electrical shorting within the LED chip. In some instances, such migration may be sufficient to adversely impact operating performance, such as causing increased current leakage, or even catastrophic LED chip failure. Furthermore, common metals for reflective layers may exhibit low adhesion within LED chip structures, leading to problems of delamination. For some deposition techniques, the reduced adhesion may lead to edge artifacts during photolithography lift-off steps of LED chip fabrication. Edge damage artifacts may embody additional material, such as material tags, that extends from intended edges of layers after lift-off.

According to aspects of the present disclosure, a metal reflective layer is provided with a material structure that promotes improved mechanical stability and improved adhesion. In certain aspects, a metal reflective layer is formed with a first metal that provides increased reflectivity and a second metal that promotes mechanical stability, improved adhesion, and reduced electromigration. Relative concentrations of the second metal may be nonuniform through a thickness of the metal reflective layer relative to the first metal.

In certain embodiments, the first metal may be provided with an increased concentration relative to the second metal in a first region, such as a center region between opposing faces of the metal reflective layer, and the second metal may be provided with an increased concentration relative to the first metal in a second region at or near an interface formed by the metal reflective layer and another LED chip layer. In certain embodiments, the second metal may be provided with an increased concentration relative to the first metal at second and third regions formed by opposing interfaces of the metal reflective layer and two LED chip layers formed on opposing sides of the metal reflective layer. A concentration of the second metal may form a gradient from high to low within the second and/or third regions in a direction toward the first region. In a corresponding manner, a concentration of the first metal may form a gradient from low to high within the second and/or third regions in a direction toward the first region. In certain embodiments, the first region may have one or more portions that are devoid of the second metal.

In certain embodiments, the first and second metals may include different ones of Ag, In, Sn, Zn, or tin-silver-copper (SAC). For example, the first metal may comprise Ag that exhibits increased reflectivity for light emitting by the active LED structure, and the second metal may include one of In, Sn, Zn, or SAC. In a specific example, the first metal comprises Ag and the second metal comprises In. Accordingly, the second and third regions of the metal reflective layer may be formed of silver indium and represented by the formula AgxIn, where x is in a range from 0.1 to 2, depending on the gradient location within the metal reflective layer.

Exemplary methods for forming the metal reflective layer may include forming a layer of the second metal followed by a separate layer of the first metal. The layers of the first and second metals may then be subjected to an anneal process where the previously discrete layers diffuse together to form a single layer for the metal reflective layer with varying concentrations of the first and second metals. During the anneal process, the second metal may diffuse into the first metal to form the gradient concentrations. By positioning the layer of the second metal first, the second metal is thereby provided with increased concentrations at an interface with an underlying portion of the LED chip to promote improved mechanical stability and adhesion. During the annealing process, the second metal may exhibit increased surface wetting relative to the first metal to promote enhanced bonding and an improved nucleation layer for the first metal. The corresponding region of the metal reflective layer proximate the interface may thereby form with concentrations of both the first and second metals. In a similar manner, another exemplary method includes forming a layer of the second metal on both sides of the layer of the first metal, thereby sandwiching the layer of the first metal between opposing layers of the second metal. After annealing, the concentration of the second metal may diffuse with gradient concentrations from both interfaces of the metal reflective layer.

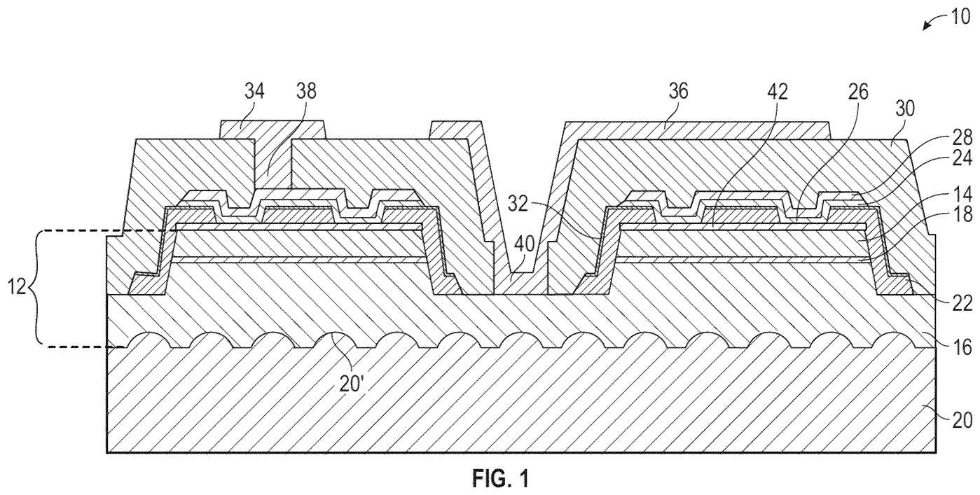

FIG. 1 is a cross-sectional view of an exemplary LED chip 10 according to principles of the present disclosure. The LED chip 10 includes an active LED structure 12 comprising a p-type layer 14, an n-type layer 16, and an active layer 18 therebetween. The active LED structure 12 may be formed on a substrate 20. In certain embodiments, one or more buffer layers and/or undoped layers may be provided between the substrate 20 and n-type layer 16 of the active LED structure 12. In certain embodiments, the n-type layer 16 is between the active layer 18 and the substrate 20. In other embodiments, the doping order may be reversed. The substrate 20 can comprise many different materials such as SiC or sapphire and can have one or more surfaces that are shaped, textured, or patterned to enhance light extraction. In certain embodiments, the substrate 20 is light transmissive (preferably transparent) and may include a patterned surface 20′ that is proximate the active LED structure 12 and includes multiple recessed and/or raised features.

In FIG. 1, a dielectric reflective layer 22 is provided on portions of the p-type layer 14. The dielectric reflective layer 22 may comprise many different materials and preferably comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. In certain embodiments, the dielectric reflective layer 22 comprises a material with an index of refraction lower than the index of refraction of the active LED structure 12 material. The dielectric reflective layer 22 may comprise many different materials, with some having an index of refraction less than 2.3, while others can have an index of refraction less than 2.15, less than 2.0, and less than 1.5. In certain embodiments, the dielectric reflective layer 22 comprises silicon dioxide (SiO₂) and/or silicon nitride (SiN). It is understood that many dielectric materials can be used such as SiN, SiNx, Si₃N₄, Si, germanium (Ge), SiO₂, SiOx, titanium dioxide (TiO₂), tantalum pentoxide (Ta₂O₅), ITO, magnesium oxide (MgOx), zinc oxide (ZnO), and combinations thereof. In certain embodiments, the dielectric reflective layer 22 may include multiple alternating layers of different dielectric materials, e.g., alternating layers of SiO₂ and SiN that symmetrically repeat or are asymmetrically arranged. Some Group III nitride materials such as GaN can have an index of refraction of approximately 2.4, SiO₂ can have an index of refraction of approximately 1.48, and SiN can have an index of refraction of approximately 1.9. Embodiments with the active LED structure 12 comprising GaN and the dielectric reflective layer 22 comprising SiO₂ may have a sufficient index of refraction step between the two to allow for efficient TIR of light. The dielectric reflective layer 22 may have different thicknesses depending on the type of materials used, with some embodiments having a thickness of at least 0.2 microns (μm). In some of these embodiments, the dielectric reflective layer 22 can have a thickness in the range of 0.2 μm to 0.7 μm, while in some of these embodiments the thickness can be approximately 0.5 μm. Portions of the dielectric reflective layer 22 may extend along mesa sidewalls of the active LED structure 12 and along sidewall portions of the p-type layer 14, the active layer 18, and the n-type layer 16.

The LED chip 10 may further include a metal reflective layer 24 that is on the dielectric reflective layer 22 such that the dielectric reflective layer 22 is arranged between the active LED structure 12 and the metal reflective layer 24. The metal reflective layer 24 forms a structure configured to reflect any light from the active LED structure 12 that may pass through the dielectric reflective layer 22. According to aspects of the present disclosure, the metal reflective layer 24 may comprise first and second metals with varying concentrations that promote high reflectivity while also provided improved mechanical stability, improved adhesion, and reduced electromigration. Exemplary materials for the first and second metals include different ones of Ag, In, Sn, Zn, or tin-silver-copper (SAC). As illustrated, the metal reflective layer 24 may include one or more reflective layer interconnects 26 that provide electrically conductive paths through the dielectric reflective layer 22 to the p-type layer 14. In certain embodiments, the reflective layer interconnects 26 comprise reflective layer vias. In some embodiments, the reflective layer interconnects 26 comprise the same material as the metal reflective layer 24 and are formed at the same time as the metal reflective layer 24. In other embodiments, the reflective layer interconnects 26 may comprise a different material than the metal reflective layer 24.

The LED chip 10 may also comprise a barrier layer 28 on a side of the metal reflective layer 24 opposite the dielectric reflective layer 22 to prevent migration of metals of the metal reflective layer 24 material to other layers. Preventing this migration helps the LED chip 10 maintain efficient operation through its lifetime. The barrier layer 28 may comprise an electrically conductive material, with suitable materials including but not limited to sputtered Ti/Pt followed by evaporated Au bulk material or sputtered Ti/Ni followed by an evaporated Ti/Au bulk material.

A passivation layer 30 may be included on the barrier layer 28 as well as any portions of the metal reflective layer 24 that may be uncovered by the barrier layer 28. The passivation layer 30 may further be arranged on portions of the dielectric reflective layer 22 that are uncovered by the metal reflective layer 24. The passivation layer 30 protects and provides electrical insulation for the LED chip 10 and can comprise many different materials, such as a dielectric material. In certain embodiments, the passivation layer 30 is a single layer, and in other embodiments, the passivation layer 30 comprises a plurality of layers. A suitable material for the passivation layer 30 includes but is not limited to SiN, SiNx, and/or Si₃N₄. In certain embodiments, the dielectric reflective layer 22 comprises SiO₂ and the passivation layer 30 comprises SiN, SiNx, or Si₃N₄. In other embodiments, the dielectric reflective layer 22 and at least a portion of the passivation layer 30 may each comprise SiO₂. As illustrated, the dielectric reflective layer 22 may bound perimeter and/or sidewall portions of the active LED structure 12, including the p-type layer 14, the active layer 18, and the n-type layer 16, along a perimeter of the LED chip 10. Furthermore, the passivation layer 30 may be arranged to also bound perimeter portions of the active LED structure 12. In this manner, portions of the dielectric reflective layer 22 may be arranged between portions of the passivation layer 30 along sidewalls of the active LED structure 12 for enhanced passivation and protection.

Certain embodiments may also comprise one or more adhesion layers 32 positioned at one or more interfaces between the dielectric reflective layer 22 and the metal reflective layer 24 to promote improved adhesion therebetween. Many different materials can be used for the adhesion layer 32, such as titanium oxide (TiO, TiO₂), titanium oxynitride (TiON, TiₓO_{y}N), tantalum oxide (TaO, Ta₂O₅), tantalum oxynitride (TaON), aluminum oxide (AlO, AlₓO_{y}) or combinations thereof, with a preferred material being TiON, AlO, or AlₓO_{y}. In certain embodiments, the adhesion layer 32 comprises AlₓO_{y}, where 1≤x≤4 and 1≤y≤6. In certain embodiments, the adhesion layer 32 comprises AlₓO_{y}, where x=2 and y=3, or Al₂O₃. The adhesion layer 32 may be deposited by electron beam deposition that may provide a smooth, dense, and continuous layer without notable variations in surface morphology. The adhesion layer 32 may also be deposited by sputtering, chemical vapor deposition, plasma enhanced chemical vapor deposition, or atomic layer deposition (ALD). In certain embodiments, the improved adhesion provided by the metal reflective layer 24 may be sufficient to omit the adhesion layer 32. In other embodiments, the adhesion layer 32 and the improved adhesion provided by the metal reflective layer 24 may be implemented together.

In FIG. 1, the LED chip 10 comprises a p-contact 34 and an n-contact 36 that are arranged on the passivation layer 30 and are configured to provide electrical connections with the active LED structure 12. The p-contact 34, which may also be referred to as an anode contact, may comprise one or more p-contact interconnects 38 that extend through the passivation layer 30 to the barrier layer 28 or the metal reflective layer 24 to provide an electrical path to the p-type layer 14. In certain embodiments, the one or more p-contact interconnects 38 comprise one or more p-contact vias. The n-contact 36, which may also be referred to as a cathode contact, is electrically coupled to the n-type layer 16 by way of one or more n-contact interconnects 40 that extend through the passivation layer 30, the barrier layer 28, the dielectric reflective layer 22, the metal reflective layer 24, the p-type layer 14, and the active layer 18. In certain embodiments, the one or more n-contact interconnects 40 may be referred to as one or more n-contact vias. Openings for the n-contact interconnects 40 may be formed in a separate etching step than etching along the perimeter of the LED chip 10 where the passivation layer 30 bounds the active LED structure 12. For illustrative purposes, FIG. 1 is shown with a single n-contact interconnect 40. In practice, the LED chip 10 may include multiple n-contact interconnects 40 spaced apart in an array pattern across the active LED structure 12.

In certain embodiments, a current spreading layer 42 may be provided between the p-type layer 14 and the dielectric reflective layer 22. The current spreading layer 42 may include a thin layer of a transparent conductive oxide such as indium tin oxide (ITO) or a thin metal layer such as Pt, although other materials may be used. As illustrated, the one or more reflective layer interconnects 26 may contact the current spreading layer 42 to provide electrically conductive pathways to the active LED structure 12.

In operation, a signal applied across the p-contact 34 and the n-contact 36 is conducted to the p-type layer 14 and the n-type layer 16, causing the LED chip 10 to emit light from the active layer 18. The p-contact 34 and the n-contact 36 can comprise many different materials such as Au, copper (Cu), nickel (Ni), In, Al, Ag, tin (Sn), Pt, or combinations thereof. In still other embodiments, the p-contact 34 and the n-contact 36 can comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used can depend on the location of the contacts and on the desired electrical characteristics, such as transparency, junction resistivity, and sheet resistance. In certain embodiments, the LED chip 10 is arranged for flip-chip mounting and the p-contact 34 and n-contact 36 are configured to be mounted or bonded to a surface, such as a printed circuit board. While FIG. 1 is described in the context of a flip-chip structure, the principles disclosed are readily applicable to other chip structures.

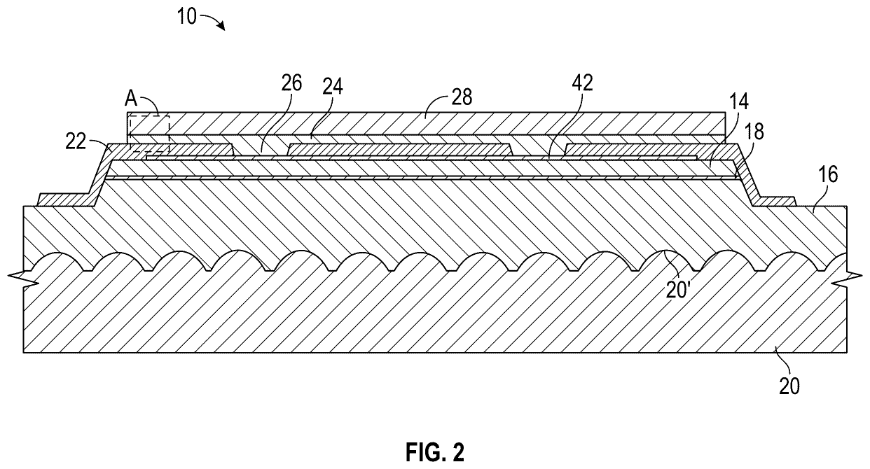

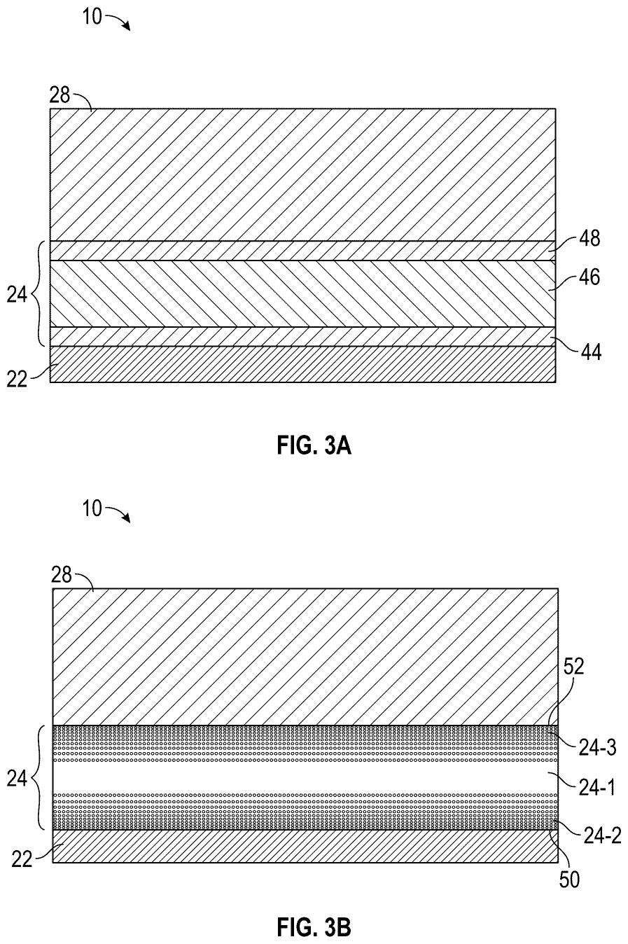

FIG. 2 is a cross-sectional view of a portion of the LED chip 10 of FIG. 1 at a fabrication step after formation of the metal reflective layer 24 and the barrier layer 28. In the example of FIG. 2, the adhesion layer 32 of FIG. 1 is omitted. However, the principles described herein are applicable to embodiments where one or more portions of the adhesion layer 32 are present between the metal reflective layer 24 and the dielectric reflective layer 22. For illustrative purposes, the metal reflective layer 24 and the barrier layer 28 are represented with planar top surfaces in FIG. 2. It is understood the metal reflective layer 24 and the barrier layer 28 may also be formed with conformal top surfaces as illustrated in FIG. 1. A superimposed dashed line box A is provided to illustrate portions of the LED chip that will be described in greater detail below with respect to FIG. 3A to FIG. 6.

FIG. 3A is a cross-sectional view of a portion of the LED chip 10 of FIG. 2 at a fabrication step before an annealing process is employed to form the metal reflective layer 24 with nonuniform distributions of the second metal relative to the first metal. The view provided in FIG. 3A is taken from the superimposed dashed line box A of FIG. 2. In FIG. 3A, the location of the metal reflective layer 24 to be formed is labeled for illustrative purposes. It is appreciated that the metal reflective layer 24 is formed after the annealing process with respect to the view provided by FIG. 3B. Accordingly, FIG. 3B is a cross-sectional view of a portion of the LED chip 10 of FIG. 3A at a subsequent fabrication step after annealing to form the metal reflective layer 24. As described above, the first and second metals may include different ones of Ag, In, Sn, Zn, or SAC. For example, the first metal may comprise Ag for increased reflectivity, and the second metal may include one of In, Sn, Zn, or SAC. In a specific example, the first metal comprises Ag and the second metal comprises

### In.

As depicted in FIG. 3A, the fabrication sequence for forming the metal reflective layer 24 includes forming a first layer 44 comprising the second metal on the dielectric reflective layer 22, followed by forming a second layer 46 comprising the first metal on the first layer 44. In certain embodiments, the fabrication sequence may further include forming a third layer 48 comprising the second metal on the second layer 46. The barrier layer 28 may then be formed on the third layer 48. The first layer 44, the second layer 46, and the third layer 48 may be formed by any of the deposition techniques described above for the metal reflective layer 24, including sputtering, evaporation, electron beam deposition, ion assisted electron beam deposition, and thermal evaporation, among other physical vapor deposition processes.

As depicted in the sequence from FIG. 3A to FIG. 3B, the annealing process diffuses the first, second, and third layers 44, 46, 48 together to form the single layer of the metal reflective layer 24 of FIG. 3B. During annealing, the second metal of the first layer 44 and/or the second metal of the third layer 48 effectively diffuses toward the location of the previous second layer 46. After annealing, the metal reflective layer 24 comprises a first region 24-1, a second region 24-2, and a third region 24-3. The concentration of the second metal thereby forms a first gradient within the second region 24-2 that progressively decreases in a direction toward the first region 24-1. In this manner, the second region 24-2 may include both the first metal and the second metal with inverse concentrations according to the first gradient. In a similar manner, the concentration of the second metal forms a second gradient within the third region 24-3 that also progressively decreases in a direction toward the first region 24-1. Accordingly, the third region 24-3 may also include both the first metal and the second metal with inverse concentrations according to the second gradient. In the context of Ag for the first metal and In for the second metal, the second and third regions 24-2, 24-3 of the metal reflective layer 24 may form silver indium. In certain embodiments, the silver indium may be represented by the formula AgxIn, where x is in a range from 0.1 to 2, depending on the gradient location within the metal reflective layer 24.

The time and or temperature of the annealing may be controlled to ensure formation of the first and second gradients. In this manner, the first region 24-1 may predominately include the first metal that provides increased reflectivity relative to the second metal. In certain embodiments, the first region 24-1 may have one or more portions that are entirely devoid of the second metal. The second region 24-2 may form a first interface 50 with the dielectric reflective layer 22, and the third region 24-3 may form a second interface 52 with the barrier layer 28. The second region 24-2 and/or the third region 24-3 may include higher concentrations of the second metal relative to the first metal, particularly at the respective interfaces 50, 52 with the dielectric reflective layer 22 and the barrier layer 28. Accordingly, the higher concentrations of the second metal in these locations may provide increased mechanical stability, increased adhesion, and reduced electromigration. In certain embodiments, the third layer 48 of FIG. 3A may be omitted such that the third region 24-3 of FIG. 3B is not present. In certain embodiments, the annealing sequence from FIG. 3A to FIG. 3B is performed after the barrier layer 28 is formed.

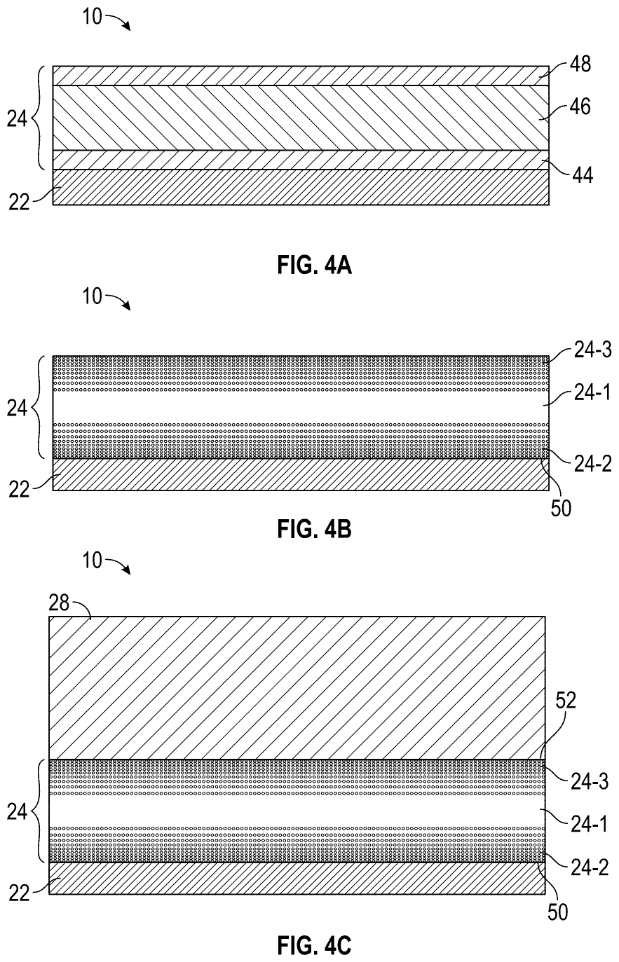

FIGS. 4A to 4C are cross-sectional views of the LED chip 10 for an alternative annealing sequence from FIGS. 3A to 3B where annealing is performed before the barrier layer 28 is formed. In FIG. 4A, the first layer 44, the second layer 46, and the third layer 48 are formed in a similar manner as described above with respect to FIG. 3A. As depicted by FIG. 4B, the annealing occurs before the later-formed barrier layer 28 of FIG. 4C. Accordingly, the first region 24-1, the second region 24-2, and the third region 24-3 with nonuniform distributions of the second metal relative to the first metal are provided. As depicted by FIG. 4C, the barrier layer 28 may then be formed after the metal reflective layer 24 is annealed.

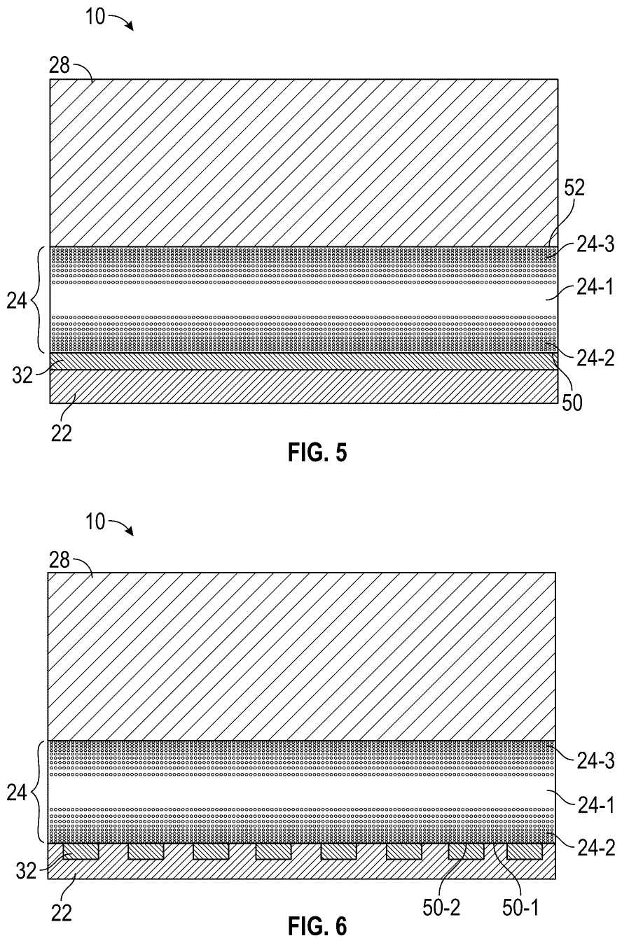

FIG. 5 is a cross-sectional view of the LED chip 10 similar to FIG. 3B or FIG. 4C for embodiments that include the adhesion layer 32. As illustrated, the second region 24-2 of the metal reflective layer 24 forms the first interface 50 with the adhesion layer 32 instead of the dielectric reflective layer 22. For such embodiments, combined adhesive properties of both the metal reflective layer 24 and the adhesion layer 32 provide further enhanced adhesion and reduce instances of delamination of the metal reflective layer 24.

FIG. 6 is a cross-sectional view of the LED chip 10 similar to FIG. 5 for embodiments where the adhesion layer 32 is a discontinuous layer. As illustrated, the second region 24-2 of the metal reflective layer 24 forms first interface portions 50-1, 50-2 with the dielectric reflective layer 22 and the adhesion layer 32, respectively. For example, the adhesion layer 32 may form discontinuous areas such that the dielectric reflective layer 22 extends therethrough to also contact the metal reflective layer 24. Accordingly, the first interface portion 50-1 is formed between the metal reflective layer 24 and the dielectric reflective layer 22, and the first interface portion 50-2 is formed between the metal reflective layer 24 and the adhesion layer 32.

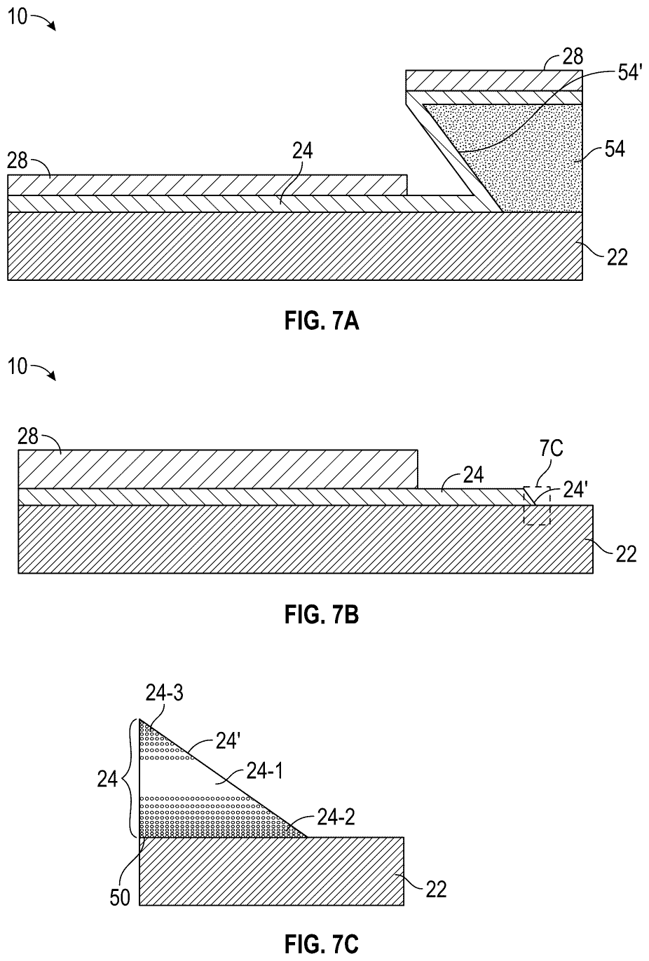

As described above, aspects of the present disclosure promote increased adhesion of the metal reflective layer 24 that may reduce instances of delamination, such as edge artifacts after photolithography lift-off steps. FIGS. 7A to 7C are cross-sectional views illustrating various fabrication steps where edge damage artifacts may be mitigated by the metal reflective layer 24. The views provided are from portions of the LED chip 10 of FIG. 1 where edges of the metal reflective layer 24 and barrier layer 28 terminate on the dielectric reflective layer 22 of FIG. 1. FIGS. 7A to 7C are provided with the adhesion layer 32 of FIG. 1 omitted. However, the principles described with respect to FIGS. 7A to 7C are also applicable when the adhesion layer 32 is present between the dielectric reflective layer 22 and the metal reflective layer 24.

FIG. 7A is a cross-sectional view of a portion of the LED chip 10 of FIG. 1 after formation of the metal reflective layer 24 and the barrier layer 28 and before photolithography lift-off. A photoresist 54 is in place on areas of the dielectric reflective layer 22 to define edge termination of the metal reflective layer 24 and barrier layer 28. Depending on the nature of deposition, the metal reflective layer 24 may conformally deposit along sidewalls 54′ of the photoresist 54.

FIG. 7B is a cross-sectional view of a portion of the LED chip 10 of FIG. 7A after lift-off of the photoresist 54 and illustrating no edge damage defects according to aspects of the present disclosure. FIG. 7C is a cross-sectional view taken from a portion of the LED chip 10 of FIG. 7B as indicated by the superimposed dashed-line box labeled 7C. The enhanced adhesion provided by the second metal in the second region 24-2 at the first interface 50 may promote clean lift-off. After lift-off, portions of the metal reflective layer 24 along the sidewalls 54′ of FIG. 7A are cleanly removed to form a well-defined edge 24′ of the metal reflective layer 24 without edge artifacts, such as a raised tag of material of the metal reflective layer 24. In certain embodiments, the edge 24′ of the metal reflective layer 24 may form an angled sidewall toward the dielectric reflective layer 22. Accordingly, portions of the edge 24′ that contact the dielectric reflective layer 22 may correspond with the second region 24-2 for increased adhesion.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip, comprising:
an active LED structure comprising an n-type layer, a p-type layer, and an active layer between the n-type layer and the p-type layer; and
a metal reflective layer on the active LED structure, the metal reflective layer comprising:
a first region and a second region, the second region being closer to the active LED structure than the first region; and
a first metal and a second metal that is different than the first metal, a concentration of the first metal being higher than a concentration of the second metal in the first region, and the concentration of the second metal being higher than the concentration of the first metal in the second region.

2. The LED chip of claim 1, wherein the concentration of the second metal forms a first gradient that decreases within the second region in a direction toward the first region.

3. The LED chip of claim 2, further comprising a dielectric reflective layer between the metal reflective layer and the active LED structure, the second region being closer to the dielectric reflective layer than the first region.

4. The LED chip of claim 3, wherein the second region forms a first interface between the metal reflective layer and the dielectric reflective layer.

5. The LED chip of claim 3, further comprising an adhesion layer between the metal reflective layer and the dielectric reflective layer, wherein the second region forms a first interface between the metal reflective layer and the adhesion layer.

6. The LED chip of claim 5, wherein the adhesion layer is discontinuous such that the second region further forms the first interface between the metal reflective layer and both of the dielectric reflective layer and the adhesion layer.

7. The LED chip of claim 2, wherein the metal reflective layer further comprises a third region, wherein:
the third region is farther away from the active LED structure than both the first region and the second region;
the concentration of the second metal is higher than the concentration of the first metal in the third region; and
the concentration of the second metal forms a second gradient that decreases within the third region in a direction toward the first region.

8. The LED chip of claim 7, further comprising a barrier layer on the metal reflective layer, wherein the third region forms a second interface between the metal reflective layer and the barrier layer.

9. The LED chip of claim 1, wherein the first metal comprises silver and the second metal comprises indium.

10. The LED chip of claim 1, wherein the first metal comprises silver and the second metal comprises at least one of one of tin, zinc, or tin-silver-copper.

11. A method for forming a light-emitting diode (LED) chip, the method comprising:
forming an active LED structure comprising an n-type layer, a p-type layer, and an active layer between the n-type layer and the p-type layer; and
forming a metal reflective layer having a first metal and a second metal on the active LED structure, the forming the metal reflective layer comprising:
depositing a first layer comprising the second metal on the active LED structure;
depositing a second layer comprising the first metal on the first layer; and
annealing the first layer and the second layer to form the metal reflective layer with a nonuniform distribution of the second metal relative to the first metal.

12. The method of claim 11, wherein the nonuniform distribution comprises a first region and a second region, wherein the second region is closer to the active LED structure than the first region, wherein a concentration of the first metal is higher than a concentration of the second metal in the first region, and the concentration of the second metal is higher than the concentration of the first metal in the second region.

13. The method of claim 12, wherein the concentration of the second metal forms a first gradient that decreases within the second region in a direction toward the first region.

14. The method of claim 13, further comprising forming a dielectric reflective layer between the metal reflective layer and the active LED structure, the second region being closer to the dielectric reflective layer than the first region.

15. The method of claim 14, wherein the second region forms a first interface between the metal reflective layer and the dielectric reflective layer.

16. The method of claim 15, wherein the nonuniform distribution comprises a third region, wherein:
the third region is farther away from the active LED structure than both the first region and the second region;
the concentration of the second metal is higher than the concentration of the first metal in the third region; and
the concentration of the second metal forms a second gradient that decreases within the third region in a direction toward the first region.

17. The method of claim 16, further comprising forming a barrier layer on the metal reflective layer after annealing the first layer and the second layer, wherein the third region forms a second interface between the metal reflective layer and the barrier layer.

18. The method of claim 16, further comprising forming a barrier layer on the metal reflective layer before annealing the first layer and the second layer, wherein the third region forms a second interface between the metal reflective layer and the barrier layer.

19. The method of claim 11, wherein the first metal comprises silver and the second metal comprises indium.

20. The method of claim 11, wherein the first metal comprises silver and the second metal comprises at least one of one of tin, zinc, or tin-silver-copper.
